(19) United States
(12) Patent Application Publication
(10) Pub. No.: US 2009/0047993 A1
(43) Pub. Date: Feb. 19, 2009

(54) METHOD OF USING MUSIC METADATA TO SAVE MUSIC LISTENING PREFERENCES

(76) Inventor: Yojak H. Vasa, Cary, NC (US)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(21) Appl. No.: 11/838,405

(22) Filed: Aug. 14, 2007

(51) Int. Cl. H04M 1/00; H03G 5/00

(52) U.S. Cl. 455/556.1; 381/103; 700/94

(57) ABSTRACT

To improve the consumer experience with electronic devices, an improved system and method is provided for selecting and applying optimal settings for listening to digital music. In exemplary embodiments, optimal equalizer settings for a given song or music category may be stored in the metadata of the music file. When the song is played by an electronic device, the optimal equalizer settings are extracted from the music metadata. The equalizer of the electronic device then may adjust automatically to the optimal settings as extracted from the metadata. The optimal settings may be defined by a content provider or selected by a user as a series of personal preferences. By adjusting the equalizer settings automatically to the optimal settings, enjoyment of the music may be enhanced.

### TECHNICAL FIELD OF THE INVENTION

The technology of the present disclosure relates generally to portable electronic devices, and more particularly to a portable electronic device that uses music metadata to save a user's preferred equalizer settings for listening to music.

### DESCRIPTION OF THE RELATED ART

Portable electronic devices commonly have the capability to play music. Different users, however, may have different listening preferences, even when listening to the same song. For example, some users may prefer a substantial amount of bass, whereas other users may wish to emphasize certain instruments, and so on. There currently appears to be no convenient method for users to set listening preferences or settings in a manner that accommodates the user's tastes while achieving maximum portability and ease of operation.

Portable electronic devices, such as mobile telephones, media players, personal digital assistants (PDAs), and others, are ever increasing in popularity. To avoid having to carry multiple devices, portable electronic devices are now being configured to provide a wide variety of functions. For example, a mobile telephone may no longer be used simply to make and receive telephone calls. A mobile telephone may also be a camera, an Internet browser for accessing news and information, an audiovisual media player, a messaging device (text, audio, and/or visual messages), a gaming device, a personal organizer, and have other functions as well.

For decades, music players, such as stereo systems and radios, have been equipped with equalizers. The conventional equalizer permits a user to adjust the gain to be applied to various frequency components or bands within the music. For example, if a user desires more bass, the user may increase the gain of the low frequency band or bands on the equalizer. Similarly, by adjusting the various frequency bands, a user may emphasize particular instruments or vocals. In this manner, a user may adjust the music playback to suit his or her individual listening tastes. Equalizers commonly are incorporated into portable electronic devices and computers that play music.

With respect to acquiring digital music in an electronic device, a user may download music files over the Internet or other communications network and store the downloaded files within memory in the device. Music files also may be streamed to the device over the Internet or other communications network, either from a recorded source or from a live broadcast or feed. Various known streaming methods are available to wireless devices, which may employ known methods such as RTP/RTSP standards to control the streaming session. As an alternative delivery method, music often may be delivered as an FM radio broadcast within the Radio Data System (RDS). RDS broadcasts and music playback incorporate information about the music, typically the song title and artist. A radio or other music receiving player that is RDS capable may display the RDS information on a display as the song is played. Music also may be shared among electronic devices pursuant to standards set forth by the Digital Living Network Alliance (DLNA). The DLNA standards are industry standards established to permit the sharing of digital data and media among various portable and home electronic devices.

Regardless of how a digital music file is received in an electronic device, the music file typically contains associated “metadata” information. Generally, metadata may be thought of as digital data providing information about other digital data or files. For example, when one takes a picture with a digital camera, metadata associated with the picture file may include such information as the date and time the picture was taken, the file size, an identifier (such as a title, file name, or number), and/or other items of information about the picture. Document files, video files, emails, and other file types similarly may contain metadata that provide various information about the associated files. The metadata may be contained within XML descriptive fields within the file.

Like other digital data files, digital musical files typically contain metadata information about the music file. For example, the metadata may include the song title, genre, artist, beats per minute, length, common instruments, and other items of information that describe aspects of the music. When digital music is conveyed over networks or by digital broadcasts, certain items of metadata are commonly included within the music files, such as title, artist, and beats per minute. There also exist applications or programs that permit a user to define and customize metadata. For example, a user may wish to add a metadata field to describe a category or “mood” to be associated with one or more music files to customize or organize songs into personal groupings, such as party music, relaxation music, travel music, or others.

Despite the common presence of digital music player functionality in electronic devices, there still appears to be deficiencies in the manner by which users may select and apply optimal listening conditions.

### SUMMARY

To improve the consumer experience with electronic devices, there is a need in the art for an improved system and method for selecting and applying optimal settings for listening to digital music. In exemplary embodiments of the present invention, optimal equalizer settings for a given song or music category may be stored in the metadata of the music file. When the song is played by an electronic device, the optimal equalizer settings are extracted from the music metadata. The equalizer in the electronic device then may adjust automatically to the optimal settings as extracted from the metadata. The optimal settings may be defined by a content provider or selected by the user as a series of personal preferences. By adjusting the equalizer settings automatically to the optimal settings, enjoyment of the music is enhanced.

Therefore, according to one aspect of the invention, a first electronic device includes a media player for playing a media file, an equalizer in communication with the media player, an input device for inputting equalizer settings, and a controller, wherein the controller is configured to receive the equalizer settings from the input device and store the equalizer settings within the media file.

According to one embodiment of the first electronic device, the controller is configured to store the equalizer settings in metadata within the media file.

According to one embodiment of the first electronic device, the media file is a music file.

According to one embodiment of the first electronic device, the controller is further configured to extract equalizer settings from the media file, and cause the equalizer to adjust to conform to the extracted equalizer settings, such that the media player plays the media file in accordance with the extracted equalizer settings.

According to one embodiment of the first electronic device, the electronic device is a mobile telephone.

According to another aspect of the invention, a second electronic device includes a media player, an equalizer in communication with the media player, an input device for inputting equalizer settings for at least one media file, and a controller, wherein the controller is configured to receive the equalizer settings from the input device and store the equalizer settings within the electronic device, and the controller is further configured identify a media file for which equalizer settings are stored and cause the equalizer to adjust to conform to the stored equalizer settings, such that the media player plays the media file in accordance with the stored equalizer settings.

According to one embodiment of the second electronic device, the media files are music files.

According to one embodiment of the second electronic device, the music file to be played by the media player is a streamed music file.

According to one embodiment of the second electronic device, the controller is configured to identify the music file to be played from an RDS feed.

According to one embodiment of the second electronic device, the electronic device is a mobile telephone.

According to another aspect of the invention, a system for playing a media file in an electronic device includes a media player in the electronic device for playing the media file, an equalizer in communication with the media player, and a controller, wherein the controller is configured to extract equalizer settings from the media file, and is further configured to cause the equalizer to adjust to conform to the extracted equalizer settings, such that the media player plays the media file in accordance with the extracted equalizer settings.

According to one embodiment of the system, the media file is a music file.

According to one embodiment of the system, the music file is a streamed music file.

According to one embodiment of the system, the media file has metadata, and the controller is configured to extract the equalizer settings from the metadata.

According to another aspect of the invention, a first method of playing a media file with an electronic device having a media player and an equalizer includes the steps of storing equalizer settings for at least one media file, receiving a media file to be played by the media player, determining whether equalizer settings are stored for the received media file, and if equalizer settings are stored for the received media file, adjusting the equalizer to conform to the stored equalizer settings, and playing the media file with the media player in accordance with the adjusted settings of the equalizer.

According to one embodiment of the first method, the storing step includes storing the equalizer settings in metadata within the media file, and the adjusting step includes extracting the equalizer settings from the metadata and adjusting the equalizer settings to conform to the extracted setting.

According to one embodiment of the first method, if it is determined that equalizer settings are not stored for the received media file, the method further includes inputting equalizer settings for the received media file, adjusting the equalizer to conform to the inputted equalizer settings, and playing the media file with the media player in accordance with the adjusted settings of the equalizer.

According to another aspect of the invention, a second method of playing a media file includes the steps of storing equalizer settings for the media file within a first electronic device, transferring the stored equalizer settings to a second electronic device having a media player and an equalizer in communication with the media player, adjusting the equalizer in the second electronic device to conform to the stored equalizer settings, and playing a media file with the media player of the second electronic device in accordance with the adjusted settings of the equalizer.

According to one embodiment of the second method, the equalizer settings are stored in the metadata of a media file.

According to one embodiment of the second method, at least one of the first or second electronic devices is a mobile telephone.

These and further features of the present invention will be apparent with reference to the following description and attached drawings. In the description and drawings, particular embodiments of the invention have been disclosed in detail as being indicative of some of the ways in which the principles of the invention may be employed, but it is understood that the invention is not limited correspondingly in scope. Rather, the invention includes all changes, modifications and equivalents coming within the spirit and terms of the claims appended hereto.

Features that are described and/or illustrated with respect to one embodiment may be used in the same way or in a similar way in one or more other embodiments and/or in combination with or instead of the features of the other embodiments.

It should be emphasized that the terms “comprises” and “comprising,” when used in this specification, are taken to specify the presence of stated features, integers, steps or components but do not preclude the presence or addition of one or more other features, integers, steps, components or groups thereof.

### BRIEF DESCRIPTION OF THE DRAWINGS

FIG. 1 is a schematic view of a mobile telephone as an exemplary electronic device for use in accordance with an embodiment of the present invention.

FIG. 2 is a schematic block diagram of operative portions of the mobile telephone of FIG. 1.

FIG. 3 is an exemplary display of equalizer information by the mobile telephone of FIG. 1.

FIG. 4 is an exemplary display of equalizer information by the mobile telephone of FIG. 1 in an equalizer adjustment mode in accordance with an embodiment of the present invention.

FIG. 5 is a schematic view of an exemplary system for playing music in accordance with an embodiment of the present invention.

FIG. 6 is a schematic diagram that represents portions of a typical music file.

FIG. 7 is a flowchart depicting an exemplary method that may be used in accordance with an embodiment of the present invention.

FIG. 8 is a schematic diagram of a communications system in which the mobile telephone of FIG. 1 may operate.

FIG. 9 is a schematic diagram of operative portions of an exemplary music server that may be used in accordance with an embodiment of the present invention.

FIGS. 10-12 are exemplary displays of equalizer and menu information by the mobile telephone of FIG. 1 in accordance with embodiments of the present invention.

FIG. 13 is a flowchart depicting another exemplary method that may be used in accordance with an embodiment of the present invention.

### DETAILED DESCRIPTION OF EMBODIMENTS

The present invention provides a user with a system and method for enhancing enjoyment of the playing of digital music in an electronic device. Each time a particular song is played, the equalizer in the music player of the electronic device may adjust automatically to conform to optimal equalizer settings for that song.

In exemplary embodiments, music equalizer settings may be stored in the metadata of music files. The equalizer settings may be stored in the metadata as an XML metadata field, in a tagged value format, or other format as is known in the art.

In one embodiment, the optimal equalizer settings may be defined by a media content (music) provider. For example, it may be presumed that the media content provider, as an entertainment professional, is in the best position to know which frequencies in a given song should be emphasized to maximize listening pleasure. If the music is part of a live FM broadcast, then the equalizer information may be included as part of an RDS feed. If a music file is downloaded or otherwise stored in memory in the electronic device, or streamed over the Internet or other communications network, the stored or streamed file may include the equalizer settings as part of the metadata.

In an alternative embodiment, the optimal equalizer settings may be selected by the user as a series of user preferences. The user may select the equalizer settings by genre or category of music. For example, the user may establish one set of equalizer settings for rock music, one for country, one for classical, and so on. Alternatively, the user may select equalizer settings on an individual song-by-song basis. The user may have multiple equalizer settings to match varying moods or to create playlist groups. Similarly, if music files are shared or transferred among electronic devices pursuant to DLNA standards, a user may select different equalizer standards for each electronic device to match device capabilities. For example, a user may select one group of equalizer settings for a portable MP3 music player, a second set for a mobile telephone, a third set for a home theater system, and so on. Equalizer metadata also may be shared by different users.

When a song is selected to be played, the optimal equalizer settings may be extracted from the metadata of the music file or RDS feed. The equalizer of the music player of the electronic device then may adjust automatically to the extracted optimal settings to enhance playback quality.

Embodiments of the present invention will now be described with reference to the drawings, wherein like reference numerals are used to refer to like elements throughout. It will be understood that the figures are not necessarily to scale.

The following description is made in the context of a conventional mobile telephone. It will be appreciated that the invention is not intended to be limited to the context of a mobile telephone and may relate to any type of appropriate electronic device, examples of which include a media player, a gaming device, or a desktop or laptop computer. For purposes of the description herein, the interchangeable terms “electronic equipment” and “electronic device” also may include portable radio communication equipment. The term “portable radio communication equipment,” which sometimes hereinafter is referred to as a “mobile radio terminal,” includes all equipment such as mobile telephones, pagers, communicators, electronic organizers, personal digital assistants (PDAs), smartphones, and any communication apparatus or the like.

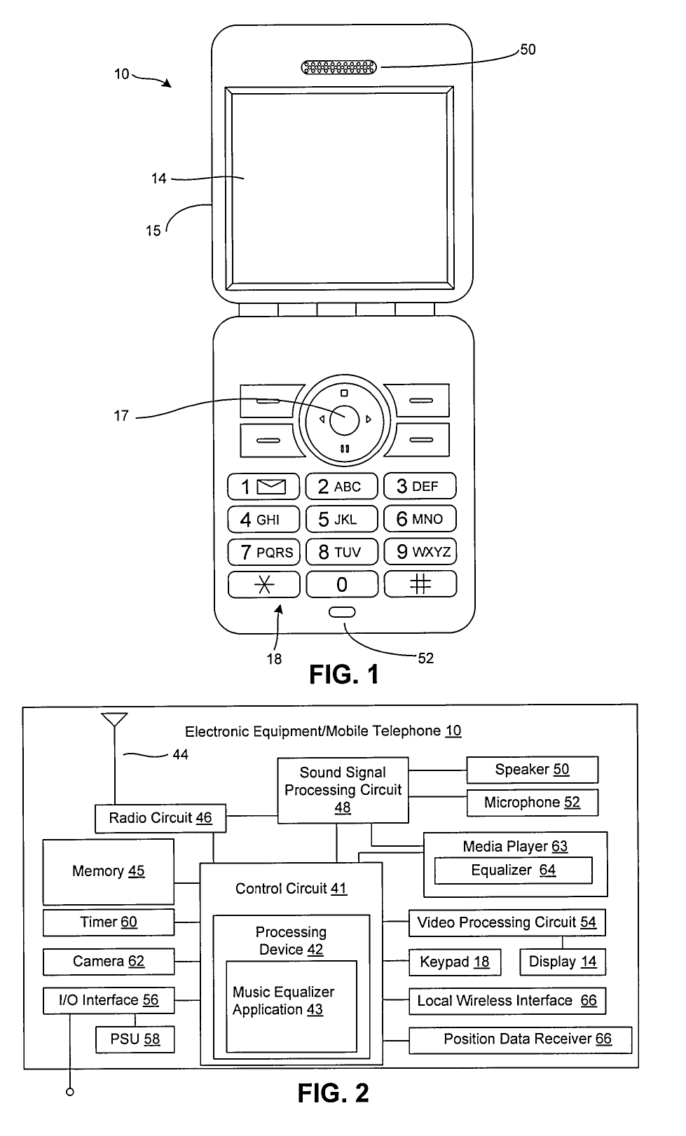

FIG. 1 depicts an exemplary mobile telephone 10. Mobile telephone 10 may be a clamshell phone with a flip-open cover 15 movable between an open and a closed position. In FIG. 1, the cover is shown in the open position. It will be appreciated that mobile telephone 10 may have other configurations, such as a “block” or “brick” configuration.

FIG. 2 represents a functional block diagram of the mobile telephone 10. The mobile telephone 10 may include a music equalizer application 43 for carrying out the features of the invention. Application 43 may be embodied as executable program code that is resident in and executed by the mobile telephone 10. The mobile telephone 10 may include a controller that executes the program code stored on a computer or machine-readable medium. The controller may include a control circuit 41 and/or a processing device 42. The program may be a stand-alone software application or form a part of a software application that carries out additional tasks related to the mobile telephone 10.

Mobile telephone 10 has a display 14 viewable when the clamshell telephone is in the open position. The display 14 displays information to a user regarding the various features and operating state of the mobile telephone 10, and displays visual content received by the mobile telephone 10 and/or retrieved from the memory 45 Also, the display 14 may be used as an electronic viewfinder for a camera assembly 62. As further described below, the display 14 also may be used to display equalizer information.

The mobile telephone 10 also may include a media player 63. The media player 63 may be used to present audiovisual content to the user which may include images and/or sound together or individually, such as photographs or other still images, music, voice or other sound recordings, movies, mobile television content, news and information feeds, streaming audio and video, and the like.

Mobile telephone 10 also may include an equalizer 64. In one embodiment, equalizer 64 may be incorporated into the media player 63. As is conventional, the equalizer may divide a sound file into component frequency portions. The sound file may include music, voice, or other sounds individually or combined. The sound file may be an independent file or may be part of a broader audiovisual file that also includes still or moving images. As further described below, the equalizer may be used to customize a sound playback by increasing the gain applied to certain frequency components and decreasing the gain applied to others.

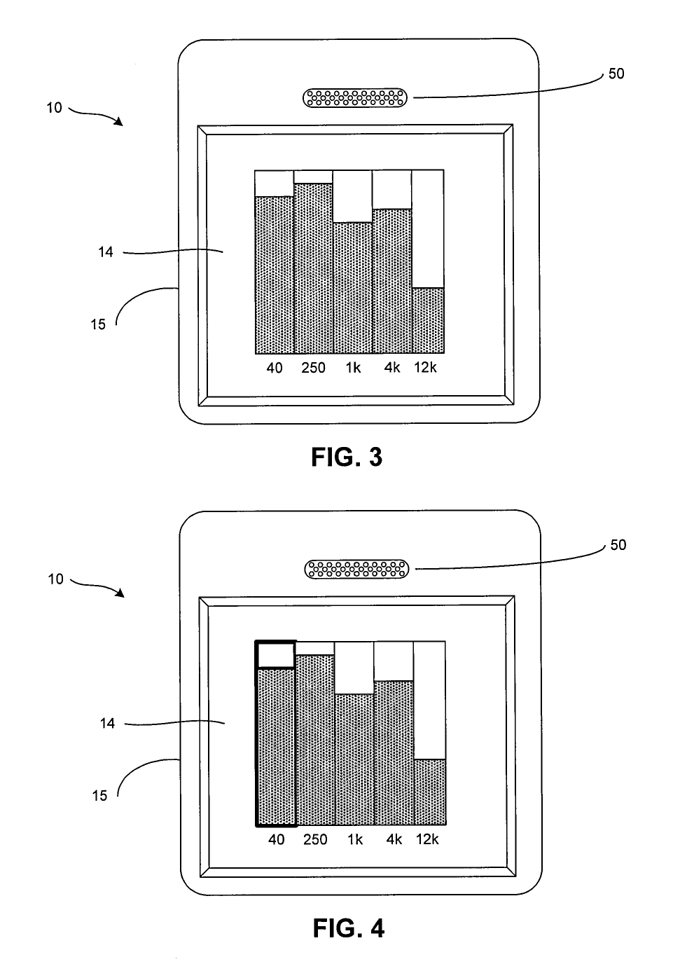

Equalizer information may be displayed on display 14. FIG. 3 depicts an exemplary display of equalizer information in which information about a sound file is displayed in manner that shows its component frequency parts. As an exemplary embodiment, the sound file is a music file with voice lyrics, although the sound file may be any of combination of music, voice, and other sounds. As shown in this example, the equalizer contains five frequency bands. The numbers generally correspond to the frequency range of each band, typically in hertz or kilohertz. In FIG. 3, the first band represents the frequency component of the music corresponding to a band centering at about 40 Hz, the next band represents the frequency component centering about a band of about 250 Hz, and so on up to a band in the 12 kHz range. It will be appreciated that an equalizer having a different number or breadth of bands may be employed.

The frequency information from the equalizer may be displayed in either a “dynamic” or a “static” mode. As used herein, the dynamic mode corresponds to the frequency spectrum displayed as music (or other sounds) are actually being played by electronic device with its media player or otherwise. For example, in FIG. 3 the shaded regions represent the relative amplitude of each frequency band within the frequency spectrum of a song being played. The higher the shaded region appears in the equalizer display, the higher the amplitude or volume of the corresponding frequency component. In this example, the music has a high amplitude in the 40 and 250 Hz bands, indicating that the song has a substantial bass component. The song has a lower amplitude of the high frequency component in the 12 kHz band. As the song plays, the shaded regions may shift in height as the amplitudes of the various frequency components change with the music.

Frequency information may also be displayed in a static mode. As used herein, the static mode corresponds to frequency information from the equalizer when no music is playing (or music is playing but frequency information for the music is not being displayed). The static mode may be used to adjust the equalizer settings to customize music playback by setting a desired gain for each frequency band. FIG. 4 is an exemplary representation of the equalizer in static mode. As shown in the figure, the first band is boldfaced, which indicates that the gain setting of this frequency band may be adjusted. For example, a user may raise the shaded bar or lower the shaded bar as desired to customize the amount of gain applied to the bass frequencies during music playback. The gains of the other frequency bands may be adjusted as well. When music is actually played, the media player may adjust the gain applied to the various frequency components of the music in accordance with the equalizer settings to provide a customized playback.

Equalizer settings may be inputted by a user in a variety of ways. Referring to FIGS. 1 and 2, in one embodiment mobile telephone 10 has a keypad 18 that provides for a variety of user input operations. For example, keypad 18 typically includes alphanumeric keys for allowing entry of alphanumeric information such as telephone numbers, phone lists, contact information, notes, etc. In addition, keypad 18 typically includes special function keys such as a “send” key for initiating or answering a call, and others. Some or all of the keys may be used in conjunction with the display as soft keys. Keys or key-like functionality also may be embodied as a touch screen associated with the display 14.

Keypad 18 also may include a five-way navigational surface 17. The navigational surface 17 may include four directional surfaces and a center “select” button. The navigational surfaces also may embody controls for the media player such as play, stop, pause, and the like. As an example, the navigational surface 17 may be used to select and adjust the equalizer settings. A user may select the equalizer display from a conventional menu displayed by the mobile telephone. Within the equalizer display, a user may navigate in the horizontal direction to select a particular frequency band, and may use a scroll-up or scroll-down feature to increase or decrease the height of the band. Alternatively, the equalizer display may be contained in a touch screen, and the bands may be adjusted using a stylus, finger, or other input instrument directly on screen.

It will be appreciated that other methods of selecting and adjusting equalizer settings may be employed. In addition, forms of display other than shaded bars may be employed to display equalizer information. In one embodiment, an electronic device may contain LEDs to indicate equalizer information rather than in an onscreen display. A user also may be able to switch between the dynamic display mode and the static display mode to permit the user to adjust the equalizer settings while music is playing.

With a typical equalizer, once the equalizer settings are selected, music (or other sound files) will be played in accordance with those settings until the settings are changed, such as in the manner described above. This may constitute an inconvenient situation, for example, when a user listens to a variety of music categories. The equalizer settings for one category of music may not provide optimal playback quality for another category. One may wish to have different equalizer settings for rock music, versus classical music, versus country music, and so on. The user may adjust the equalizer each time the music category changes, or the user may be resigned to selecting one group of equalizer settings even though the settings may not provide optimal playback for all kinds of music. In addition, even within a genre of music, optimal playback may necessitate that equalizer settings be selected on an individual song basis. For example, not every rock song has the same quality when played with a given configuration of equalizer settings.

Embodiments of the present invention enhance music (or sound) playback by providing a system and method by which optimal equalizer settings are applied automatically for any given item of music. Optimal equalizer settings may be stored within a given digital music file. When playback is initiated, the equalizer settings may be extracted from the music file. The equalizer settings may be adjusted automatically in accordance with the settings extracted from the music file, and the music is played in accordance with those settings.

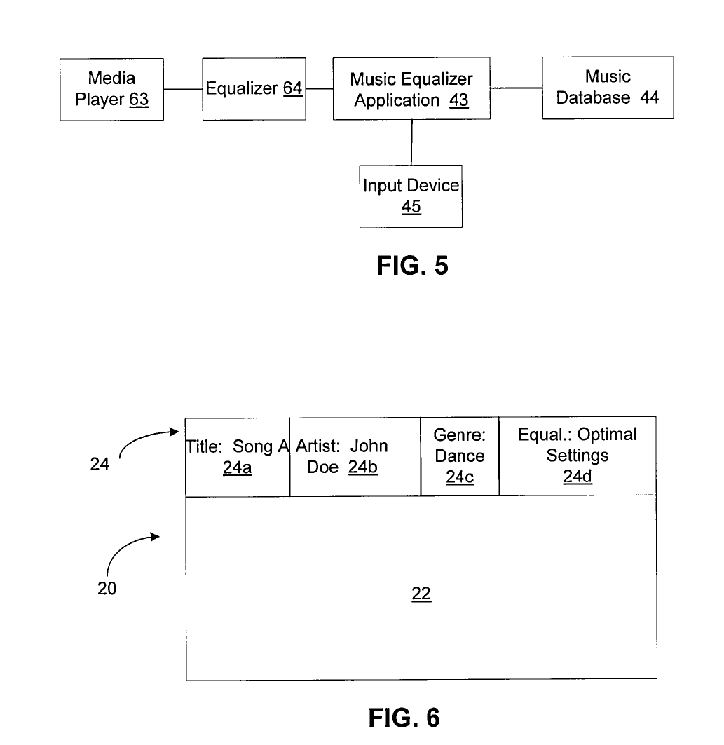

FIG. 5 is schematic view of an exemplary system for playing music with optimal equalizer settings. The music equalizer application 43 may provide an interface for the interaction of the other components of the system. Equalizer settings may be input with an input device 45. As further described below with respect to various embodiments, the optimal equalizer settings may be defined and inputted either by a content provider or by a user of an electronic device. Once the optimal equalizer settings are defined, they are stored within the music files in a music database 44. Again as further described below, the music database may be resident either in a user's electronic device or on a network storage device (or both). In addition, when the input device and/or music database are on a network, one or more functional portions of the application 43 also may be on a network. When an item of music is selected to be played, either by the user or a network content provider, application 43 may extract the optimal settings from the music file and cause the settings of equalizer 64 to adjust commensurately. Media player 63 then may play the music in accordance with the adjusted equalizer settings. More detailed exemplary embodiments will now be described.

In one embodiment, the optimal equalizer settings for a given item of music may be stored as part of the metadata of a digital music file. FIG. 6 is a schematic block diagram that represents the relevant portions of a typical music file 20. Music file 20 may include music portion 22, which may be thought of as the substantive music itself. Music portion 22 may be coded in one of a variety of digital music formats such as MIDI, MP3, or other formats as are known in the art. Music file 20 also may include associated metadata fields 24, which provide various items of information about the music. In the depicted example, the metadata includes four exemplary metadata fields: song title (24a), artist (24b) music genre (24c), and optimal equalizer settings (24d). It will be appreciated that both the number and nature of the metadata fields may be varied.

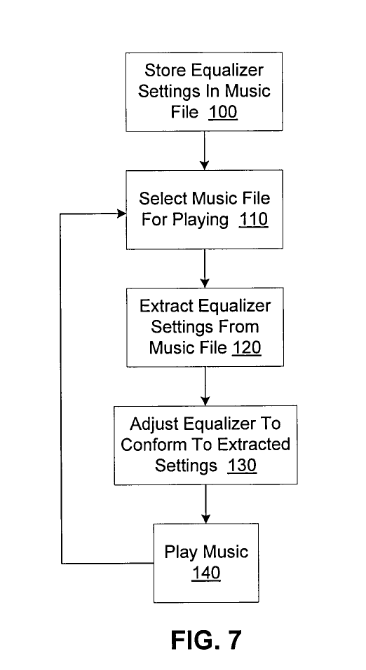

FIG. 7 depicts an exemplary method of playing a media file in accordance with an embodiment of the present invention. Although the exemplary method is described as a specific order of executing functional logic steps, the order of executing the steps may be changed relative to the order described. Also, two or more steps described in succession may be executed concurrently or with partial concurrence. It is understood that all such variations are within the scope of the present invention. The method will be described by way of example in connection with playing a music file. It will appreciated that a comparable method may be employed as to any media file containing sound, such as a voice recording, sound effects recording, and the like. In addition, a comparable method may be applied as to an audiovisual media file in which sound is present along with image components, such as a television program, movie, slideshow with music, and the like.

Referring to FIG. 7, the method begins at step 100 in which optimal equalizer settings are stored within a given digital music file or files. As stated above, the optimal equalizer settings may be stored within the metadata of the music file. In one embodiment, the optimal equalizer settings may be selected at the time the digital music file is created by an artist, a production company, or some other music content provider. An advantage of this embodiment is that an artist or content provider may be in the best position to determine the optimal equalizer settings for the highest quality playback. Another advantage of this embodiment is that a user need not expend the effort of defining the equalizer settings.

At step 110, a music file may be selected for playing in any conventional manner. Music files may be stored as a music library or database within an electronic device, such as within the memory 45 of mobile telephone 10 (see FIG. 2). Alternatively or additionally, music may be downloaded or streamed from the Internet or other communications network. A music file may be selected for playing by a user, or by a content provider as part of a broadcast or live feed.

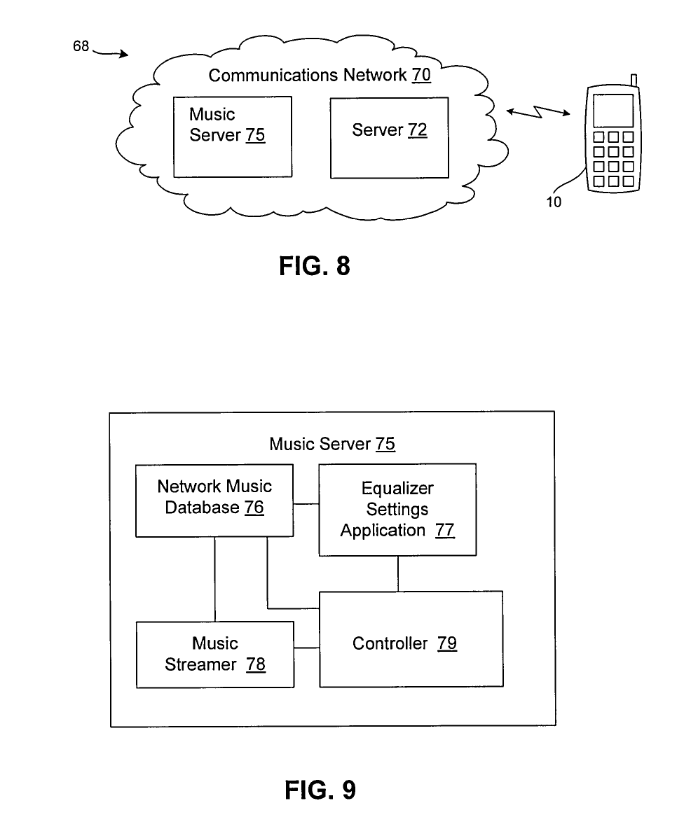

Referring to FIG. 8, the mobile telephone 10 may be configured to operate as part of a communications system 68. The system 68 may include a communications network 70 having a server 72 (or servers) for managing calls placed by and destined to the mobile telephone 10, transmitting data to the mobile telephone 10 and carrying out any other support functions. The server 72 communicates with the mobile telephone 10 via a transmission medium. The transmission medium may be any appropriate device or assembly, including, for example, a communications tower (e.g., a cell tower), another mobile telephone, a wireless access point, a satellite, etc. Portions of the network may include wireless transmission pathways. The network 70 may support the communications activity of multiple mobile telephones 10 and other types of end user devices. As will be appreciated, the server 72 may be configured as a typical computer system used to carry out server functions and may include a processor configured to execute software containing logical instructions that embody the functions of the server 72 and a memory to store such software.

Communications network 70 also may contain a music server 75. FIG. 9 represents a functional block diagram of the components of an exemplary music server 75. The music server 75 may include a network music database 76 for storing a plurality of music files. The music selection server also may include a controller 79 for carrying out and coordinating the various functions of the server. Music selection server 75 also may include an equalizer settings application 77 by which a content provider may input and store optimal equalizer settings within the music files of music database 76 (step 100 of FIG. 7). A user of an electronic device, such as mobile telephone 10, may download music files from the music database 76. In addition, music may be streamed to the electronic device by music streamer 78 of the music server. In an embodiment in which music is streamed, the streaming session may be controlled in accordance with known RTP/RTSP methods. As an alternative to storing equalizer settings in metadata, equalizer settings may be incorporated into an RDS information feed as part of an FM broadcast.

Referring again to FIG. 7, whether a music file is selected (step 110) from within the electronic device or from a network, at step 120 the optimal equalizer settings may be extracted from the music file selected to be played. In one embodiment, the mobile telephone 10 may include a primary control circuit 41 that is configured to carry out overall control of the functions and operations of the mobile telephone 10. See FIG. 2. The control circuit 41 may include a processing device 42, such as a CPU, microcontroller or microprocessor. Among their functions, to implement the features of the present invention, the control circuit 41 and/or processing device 42 may comprise a controller that may execute program code embodied as the music equalizer application 43. It will be apparent to a person having ordinary skill in the art of computer programming, and specifically in application programming for cameras, mobile telephones or other electronic devices, how to program a mobile telephone to operate and carry out logical functions associated with application 43. Accordingly, details as to specific programming code have been left out for the sake of brevity. Also, while the code may be executed by control circuit 41 in accordance with an exemplary embodiment, such controller functionality could also be carried out via dedicated hardware, firmware, software, or combinations thereof, without departing from the scope of the invention.

At step 120, application 43 may extract the optimal equalizer settings from the metadata of the music file. Application 43 may also conform or approximate the stored equalizer settings commensurately with a given equalizer's properties. For example, if a content provider defines the equalizer settings in seven frequency bands and the equalizer has only five frequency bands, application 43 may provide a “best fit” as between the stored settings and the equalizer capabilities. At step 130, application 43 may then cause the settings of the equalizer to adjust to conform to the extracted settings. At step 140, media player 63 may then play the music subject to the adjusted equalizer settings. In this manner, the equalizer settings may be individually adjusted automatically for a given song to provide optimal playback with minimal user effort. In similar fashion, the method may be repeated when the next song is selected for playing, such that the equalizer may adjust automatically to optimal settings for that song, and so on.

In addition, as shown in the loop of FIG. 7, the equalizer settings need only be defined once for each particular song or music file. Because the optimal equalizer settings are stored, optimal play may be achieved every time a given song is played without having to re-define the optimal equalizer settings for that song.

In one embodiment, at step 100 of FIG. 7, optimal equalizer settings may be stored based upon setting selections made by a user (rather than by a content provider). An advantage of this embodiment is that it provides for increased customization to enhance listening enjoyment. As an example, a user may execute equalizer application 43 of mobile telephone 10 from a menu or by another conventional manner.

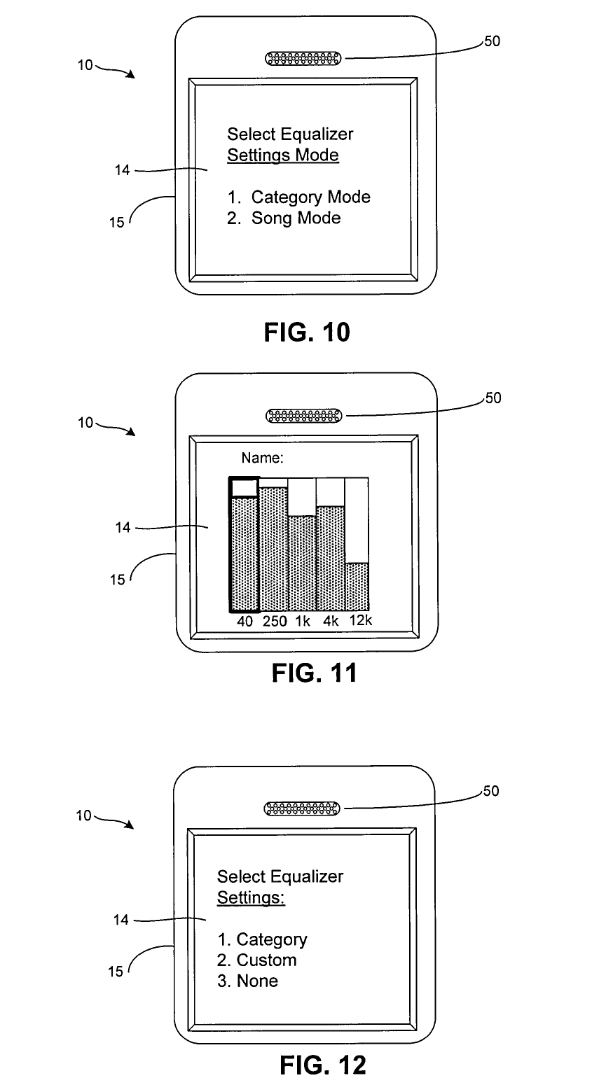

FIG. 10 represents an exemplary menu associated with music equalizer application 43. This menu affords a user two options for selecting optimal equalizer settings. In a “Category Mode”, a user may define equalizer settings for a category or genre of music, such as rock, dance, classical, country, etc. As shown in FIG. 11, a selection of the Category Mode may cause the mobile telephone to display equalizer information similar to that shown in FIG. 4. The user may enter the name of the category and may adjust the equalizer band settings as described previously. The equalizer settings for each category may then be stored in memory.

Alternatively, in FIG. 10 a user may select “Song Mode” to define optimal equalizer settings for an individual song. Again, a screen comparable to that of FIG. 11 may be displayed. In Song Mode, a user may input the name of a song or a file name for a music file. The user may then adjust the equalizer frequency band settings as described previously to be applied whenever that song is played. Alternatively, instead of adjusting the equalizer bands individually, a user may select a category of music for which a user has previously defined equalizer settings in the Category Mode. The frequency bands may then adjust automatically to the settings defined for that category. For example, if a user has defined equalizer settings for a rock music category, a user may select the rock music category in Song Mode. The equalizer bands for that song may adjust automatically in accordance with the defined rock settings. Once the equalizer settings are selected either by category or by adjusting the individual frequency bands, application 43 may store the settings within the music file, such as in the metadata.

In one embodiment, if the music file is not stored in the mobile telephone, such as when a song is streamed or broadcasted, the equalizer settings may be stored as an independent file. A song may be recognized as part of an RDS feed of an FM broadcast. FIG. 13 represents an exemplary method of applying equalizer settings to a song when the equalizer settings are stored independent of the music file. Although the exemplary method is described as a specific order of executing functional logic steps, the order of executing the steps may be changed relative to the order described. Also, two or more steps described in succession may be executed concurrently or with partial concurrence. It is understood that all such variations are within the scope of the present invention. The method will be described by way of example in connection with playing a music file. It will appreciated that a comparable method may be employed as to any media file containing sound, such as a voice recording, sound effects recording, and the like. In addition, a comparable method may be applied as to an audiovisual media file in which sound is present along with image components, such as a television program, movie, slideshow with music, and the like.

Referring to FIG. 13, at step 200, a user may select one or more music files, and at step 210 may input equalizer settings in a manner described above. At step 220, the equalizer settings may be stored, such as in the memory of the mobile telephone, independent of the substantive music portions of a file. As step 230, a user may receive a music file, such as a streamed or broadcasted music file. At step 240, application 43 may check to match the song with any of the stored equalizer settings. If equalizer settings are stored for that song, then the equalizer is adjusted to conform to the stored settings, and the music is played subject to those settings at step 260. As shown on the loop from step 260 to step 230, equalizer settings need only be stored once. When the song is streamed or broadcasted again, application 43 may recognize that equalizer settings are stored for that song, and apply the equalizer settings accordingly.

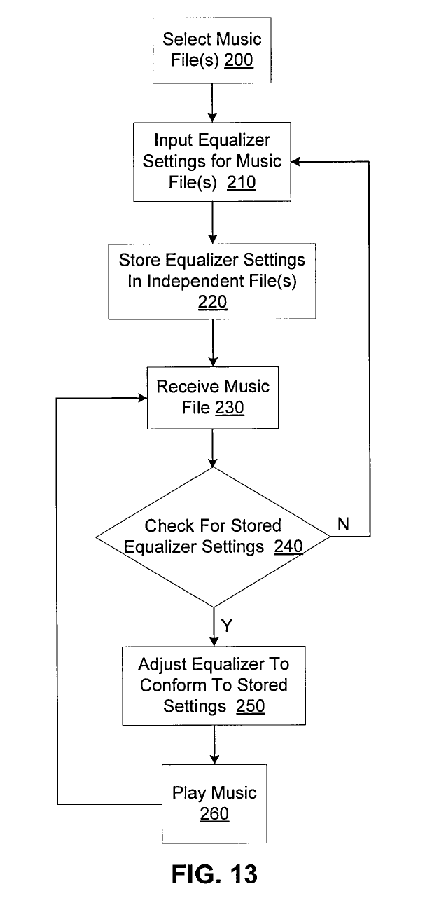

As shown at step 240 in FIG. 13, if a user receives a music file for which equalizer settings have not been selected, a user may input settings for the new music. In one embodiment, application 43 may prompt a user for an input of optimal equalizer settings the first time a song is played in the mobile telephone. The prompt may occur regardless of whether the song is first played from a stored file, streamed audio file, or other broadcast. FIG. 12 represents an exemplary prompt display for the input of equalizer settings for a new song currently playing. A user may select a category of settings for music categories for which equalizer settings may have been defined in a Category Mode, as described above. A user may select “Custom” to select equalizer settings by adjusting the frequency bands individually (see FIG. 11), or a user may decline to input equalizers settings by selecting “None”. If equalizer settings are selected, the settings may be stored and applied to subsequent playing of the music as described previously. In another embodiment, rather than being prompted automatically, a user may manually execute application 43 to access the screen of FIG. 12 as a song is being played. A user may do so to define optimal equalizer settings for the first time, or to change the equalizer settings defined previously.

In another embodiment, a user may have stored multiple equalizer settings for a given song. In such a situation, when a song is played, a user may be prompted to select from one of the multiple groups of settings. Alternatively, a user may set a certain group of equalizer settings as the default or preferred settings, which may be changed manually by the user.

It will be appreciated that the above embodiments provide examples of ways by which a user may select and store optimal equalizer settings. These examples are not meant to limit the scope of the invention, and other schemes may be employed.

A user may wish to play music on a variety of electronic devices. For example, as stated above, DNLA standards provide one mechanism for permitting communication among the various portable and home electronic devices. In one embodiment, any electronic device may be equipped with application 43 to extract the optimal equalizer settings from a music or other sound file. In addition, as part of the Category Mode described above, a user may select optimal equalizer settings by device based upon each device's playback capabilities. For example, a user may define equalizer settings categorically for a mobile telephone, a personal computer, a home theater system, and others. In addition, stored equalizer settings may be transferred to the electronic devices of other users so that listening tastes may be shared and enjoyed together. By sharing only equalizer settings and not the substantive music files, copyright violations may be avoided.

Referring again to FIG. 2, additional features of the mobile telephone 10 will now be described. For the sake of brevity, generally conventional features of the mobile telephone 10 will not be described in great detail herein. The mobile telephone 10 includes call circuitry that enables the mobile telephone 10 to establish a call and/or exchange signals with a called/calling device, typically another mobile telephone or landline telephone, or another electronic device. The mobile telephone 10 also may be configured to transmit, receive, and/or process data such as text messages (e.g., colloquially referred to by some as “an SMS,” which stands for short message service), electronic mail messages, multimedia messages (e.g., colloquially referred to by some as “an MMS,” which stands for multimedia message service), image files, video files, audio files, ring tones, streaming audio, streaming video, data feeds (including podcasts) and so forth. Processing such data may include storing the data in the memory 45, executing applications to allow user interaction with data, displaying video and/or image content associated with the data, outputting audio sounds associated with the data and so forth.

The mobile telephone 10 may include an antenna 44 coupled to a radio circuit 46. The radio circuit 46 includes a radio frequency transmitter and receiver for transmitting and receiving signals via the antenna 44 as is conventional. The mobile telephone 10 further includes a sound signal processing circuit 48 for processing audio signals transmitted by and received from the radio circuit 46. Coupled to the sound processing circuit 48 are a speaker 50 and microphone 52 that enable a user to listen and speak via the mobile telephone 10 as is conventional.

The display 14 may be coupled to the control circuit 41 by a video processing circuit 54 that converts video data to a video signal used to drive the various displays. The video processing circuit 54 may include any appropriate buffers, decoders, video data processors and so forth. The video data may be generated by the control circuit 41, retrieved from a video file that is stored in the memory 45, derived from an incoming video data stream received by the radio circuit 48 or obtained by any other suitable method.

The mobile telephone 10 also may include a local wireless interface 66, such as an infrared transceiver and/or an RF adaptor (e.g., a Bluetooth adapter), for establishing communication with an accessory, another mobile radio terminal, a computer or another device. For example, the local wireless interface 66 may operatively couple the mobile telephone 10 to a headset assembly (e.g., a PHF device) in an embodiment where the headset assembly has a corresponding wireless interface.

The mobile telephone 10 also may include an I/O interface 56 that permits connection to a variety of I/O conventional I/O devices. One such device is a power charger that can be used to charge an internal power supply unit (PSU) 58.

Although the invention has been shown and described with respect to certain preferred embodiments, it is understood that equivalents and modifications will occur to others skilled in the art upon the reading and understanding of the specification. The present invention includes all such equivalents and modifications, and is limited only by the scope of the following claims.

What is claimed is:

1. An electronic device comprising:
a media player for playing a media file;
an equalizer in communication with the media player;
an input device for inputting equalizer settings; and
a controller, wherein the controller is configured to receive the equalizer settings from the input device and store the equalizer settings within the media file.

2. The electronic device according to claim 1, wherein the controller is configured to store the equalizer settings in metadata within the media file.

3. The electronic device according to claim 1 wherein the media file is a music file.

4. The electronic device according to claim 1, wherein the controller is further configured to extract equalizer settings from the media file, and cause the equalizer to adjust to conform to the extracted equalizer settings, such that the media player plays the media file in accordance with the extracted equalizer settings.

5. The electronic device according to claim 1, wherein the electronic device is a mobile telephone.

6. An electronic device comprising:
a media player;
an equalizer in communication with the media player;
an input device for inputting equalizer settings for at least one media file; and
a controller, wherein the controller is configured to receive the equalizer settings from the input device and store the equalizer settings within the electronic device, and the controller is further configured identify a media file for which equalizer settings are stored and cause the equalizer to adjust to conform to the stored equalizer settings, such that the media player plays the media file in accordance with the stored equalizer settings.

7. The electronic device according to claim 6 wherein the media files are music files.

8. The electronic device according to claim 7 wherein the music file to be played by the media player is a streamed music file.

9. The electronic device according to claim 7, wherein the controller is configured to identify the music file to be played from an RDS feed.

10. The electronic device according to claim 6, wherein the electronic device is a mobile telephone.

11. A system for playing a media file in an electronic device comprising:
a media player in the electronic device for playing the media file;
an equalizer in communication with the media player; and
a controller, wherein the controller is configured to extract equalizer settings from the media file, and is further configured to cause the equalizer to adjust to conform to the extracted equalizer settings, such that the media player plays the media file in accordance with the extracted equalizer settings.

12. The system according to claim 11, wherein the media file is a music file.

13. The system according to claim 12, wherein the music file is a streamed music file.

14. The system according to claim 11, wherein the media file has metadata, and the controller is configured to extract the equalizer settings from the metadata.

15. A method of playing a media file with an electronic device having a media player and an equalizer, comprising the steps of:
storing equalizer settings for at least one media file;
receiving a media file to be played by the media player;
determining whether equalizer settings are stored for the received media file;
if equalizer settings are stored for the received media file, adjusting the equalizer to conform to the stored equalizer settings; and
playing the media file with the media player in accordance with the adjusted settings of the equalizer.

16. The method according to claim 15, wherein the storing step includes storing the equalizer settings in metadata within the media file, and the adjusting step includes extracting the equalizer settings from the metadata and adjusting the equalizer settings to conform to the extracted settings.

17. The method according to claim 15, wherein if it is determined that equalizer settings are not stored for the received media file, the method further comprises:
inputting equalizer settings for the received media file;
adjusting the equalizer to conform to the inputted equalizer settings; and
playing the media file with the media player in accordance with the adjusted settings of the equalizer.

18. A method of playing a media file comprising the steps of:
storing equalizer settings for the media file within a first electronic device;
transferring the stored equalizer settings to a second electronic device having a media player and an equalizer in communication with the media player;
adjusting the equalizer in the second electronic device to conform to the stored equalizer settings; and
playing a media file with the media player of the second electronic device in accordance with the adjusted settings of the equalizer.

19. The method according to claim 18, wherein the equalizer settings are stored in the metadata of a media file.

20. The method according to claim 18, wherein at least one of the first or second electronic devices is a mobile telephone.
